(19) United States
(12) Patent Application Publication
(10) Pub. No.: US 2005/0205128 A1
(43) Pub. Date: Sep. 22, 2005

(54) Integrated photoelectrochemical cell and system having a solid polymer electrolyte

(75) Inventors: Xunming Deng, Sylvania, OH (US); Liwei Xu, Sylvania, OH (US)

Correspondence Address: MACMILLAN SOBANSKI & TODD, LLC;ONE MARITIME PLAZA FOURTH FLOOR, 720 WATER STREET, TOLEDO, OH, 43604-1619, US

(73) Assignee: The University of Toledo

(21) Appl. No.: 11/134,928

(22) Filed: May 23, 2005

Related U.S. Application Data
(63) Continuation of application No. PCT/US03/37733, filed on Nov. 24, 2003.
(60) Provisional application No. 60/428,841, filed on Nov. 25, 2002.

(51) Int. Cl. H01L 31/00

(52) U.S. Cl. 136/256; 136/252; 429/111

(57) ABSTRACT

A photoelectrochemical (PEC) cell includes a photovoltaic electrode that generates voltage under radiation; a solid membrane electrode assembly that includes at least one solid polymer electrolyte and first and second electrodes; a mechanism that collect gases from oxidation and reduction reactions; and an electrical connection between the photovoltaic electrode and the solid membrane electrode assembly. A PEC system and a method of making such PEC cell and PEC system are also disclosed.

### CROSS REFERENCE TO RELATED APPLICATION

This application is a continuation of co-pending International Patent Application No. PCT/US2003/37733 filed Nov. 24, 2003, claiming priority to U.S. Patent Application No. 60/428,841 filed Nov. 25, 2002. International Patent Application PCT/US0/37733 was published as WO 04/049459 on Jun. 10, 2004 in English under PCT Article 21(2).

This invention was made with Government support under National Renewable Energy Laboratory (NREL) contract No. NDJ-1-30630-08 awarded by the Department of Energy, and under ARL-WPAFB Grant “Photovoltaic Hydrogen for Portable, On-Demand Power” awarded to the University of Toledo under subcontract 03-S530-0011-01C1 under the primary contract F33615-02-D-2299 through the Universal Technology. The government has certain rights in this invention.

### FIELD OF THE INVENTION

The instant invention relates generally to the generation of hydrogen and oxygen from water through a photo-electrolysis process and more particularly to the generation of hydrogen using solar radiation.

### BACKGROUND OF THE INVENTION

Future transportation is widely believed to be based on a hydrogen economy. Using fuel cells, cars and trucks will no longer burn petroleum and will no longer emit CO₂ on the streets since they will use hydrogen as the fuel and the only byproduct is water. However, the reforming process, the main process that is used in today's hydrogen production, still uses petroleum-based products as the raw material and still emits large amounts of CO₂. To reduce our society's reliance on petroleum based products and to avoid the emission of CO₂ that causes global warming, a renewable method of generating hydrogen must be developed. An electrolysis process using only sunlight and water is considered to be a top choice for hydrogen generation. Such hydrogen fuel is ideal for proton exchange membrane fuel cell (PEM) fuel cell applications since it contains extremely low concentrations of carbon monoxide, which is poisonous to platinum catalysts in PEM fuel cells. However, indirect photo-electrolysis, in which the photovoltaic cells and electrodes are separated and connected electrically using external wires, is not cost-effective. An integrated photoelectrochemical cell (PEC) offers the potential to generate hydrogen renewably and cost effectively.

Several prior inventions and publications have disclosed designs for photoelectrochemical cells, which are fully incorporated herein by reference in their entireties. U.S. Pat. No. 4,090,933 (Nozik), U.S. Pat. No. 4,144,147 (Jarrett et al.), U.S. Pat. No. 4,236,984 (Grantham), U.S. Pat. No. 4,544,470 (Hetrick), U.S. Pat. No. 4,310,405 (Heller), U.S. Pat. No. 4,628,013 (Figard et al.), U.S. Pat. No. 4,650,554 (Gordon), U.S. Pat. No. 4,656,103 (Reichman et al.), U.S. Pat. No. 5,019,227 (White et al.), U.S. Pat. No. 6,471,850 (Shiepe et al.), U.S. Pat. No. 6,361,660 (Goldstein), U.S. Pat. No. 6,471,834 (Roe et al.)

J. R. Bolton “Solar photoproduction of hydrogen: a review”, Solar Energy, 57, 37 (1996).

S. S. Kocha, D. Montgomery, M. W. Peterson, J. A. Turner, “Photoelectrochemical decomposition of water utilizing monolithic tandem cells”, Solar Energy Materials & Solar Cells, 52, 389 (1998).

S. Licht, “Efficient solar generation of hydrogen fuel—a fundamental analysis”, Electrochemistry Communications 4, 790 (2002).

P. K. Shukla, R. K. Karn, A. K. Singh, O. N. Srivastava, “Studies on PV assisted PEC solar cells for hydrogen production through photoelectrolysis of water”, Int. J. of Hydrogen Energy, 27, 135 (2002).

X. Gao, S. Kocha, A. Frank, J. A. Turner, “Photoelectrochemical decomposition of water using modified monolithic tandem cells”, Int. J. of Hydrogen Energy, 24, 319 (1999).

R. E. Rocheleau and E. L. Miller, “Photoelectrochemical production of hydrogen: Engineering loss analysis”, Int. J. Hydrogen Energy, 22, 771 (1997).

However, the prior art devices and methods described and disclosed in these above mentioned patents and publications have at least one of the following shortcomings:
the photovoltaic cell does not generate sufficient voltage to split water,
the photovoltaic cell needs an external electrical bias for the electrolysis,
the photovoltaic device will not survive for extended use in the electrolyte due to inappropriate protection,
the photovoltaic device cannot be fabricated using low-cost methods, and/or
the photovoltaic device does not have potential for high conversion efficiency.

Therefore, there is a compelling and crucial need in the art for an efficient PEC device that produces hydrogen from water under radiation, does not require external bias due to sufficient voltage, and can be made at low cost.

### SUMMARY OF THE INVENTION

This instant invention provides a PEC cell that splits water under radiation and generates hydrogen and oxygen. This PEC cell integrates multiple-junction stacked photovoltaic structure (PV structure), to generate electricity, and a solid polymer electrolyte membrane electrode assembly (MEA) to electrolyze water, through novel interconnect schemes that lead to a device that has a high conversion efficiency, that is stable and can be made at low cost. One side of the photovoltaic structure is in direct contact with one electrode of the MEA while the other side (radiation entering side) connects to the opposite side of the MEA through appropriate interconnects such as via slots or via holes.

The PV structure uses a multiple-junction approach to generate a voltage sufficient to split water. The theoretical limit for such a voltage is 1.23V. But practically, due to the existence of overpotentials at the electrolyte/electrode interfaces, the voltage needed is approximately 1.6V or greater. The PV structure that generates such a voltage under radiation, such as sunlight, should have a voltage of approximately 1.6V or greater under operating conditions. Examples of this PV structure are two-junction or three-junction amorphous silicon alloy solar cell stacks.

The MEA structure contains a solid polymer electrolyte sandwiched between two electrodes. Examples of the polymer electrolyte are cation-exchange membranes and anion-exchange membranes. The selection of the polymer depends on the selection of chemical processes used for the oxidation and reduction half reactions at the anode and cathode, respectively. Examples of the half and combined reactions are:
2H⁺+2e⁻→H₂ (reduction at cathode)
2H₂O→4H⁺+O₂+4e⁻ (oxidation at anode)
Combined reaction: 2H₂O→2H₂+O₂ (1)
Or,
2H₂O+2e⁻→H₂+2OH⁻ (reduction at cathode)
4OH⁻→O₂+2H₂O+4e⁻ (oxidation at anode)
Combined reaction: 2H₂O→2H₂+O₂ (2)
Reaction (1), which is based on the diffusion of H⁺, can be made using cation-exchange membrane, in which H⁺ move rather freely inside. Reaction (2), which is based on the diffusion of OH⁻ in the electrolyte, can be made using anion-exchange membrane, in which OH⁻ move rather freely inside. The polarity of the MEA also depends on the polarity of the photovoltaic structure.

In certain embodiments, appropriate catalysts can be applied to the membrane to reduce overpotential and promote electrolysis. As an example, the catalysts for the electrochemical reactions can be nanoscaled platinum particles supported by micron-sized particles of carbon powder. This Pt-coated carbon powder is bounded to a supporting layer, i.e.,—the electrode. The electrode can be made using, for example, a carbon paper. The electrode not only conducts electricity, but also allows gases, hydrogen and oxygen, to diffuse out. The thin MEA is then sandwiched and protected by two opposing end plates which conduct electricity and also have channels or grooves for hydrogen and oxygen collection.

Water, needed for the electrolysis reaction, can be injected into the MEA using multiple methods. For example, water can be directed into the MEA through one or both of the gas outlet channels. The advantage of directing water through these channels is that water flushes out the gas bubbles and rapidly moves gas bubbles away from the electrodes for enhanced electrolysis.

An interconnect between the PV structure the MEA is accomplished in such a way that 1) the voltage from the PV structure is applied to the MEA; 2) radiation to the PV structure is not blocked; 3) hydrogen and oxygen can be directed out of the MEA effectively and water can be directed into the system effectively; 4) the electrical loss, if any, between PV structure and MEA is low; and, 5) the device can be fabricated using low-cost methods. In one embodiment, the PV structure is fabricated on a glass substrate. In certain embodiments, laser scribing is used to remove the photovoltaic semiconductor layers. MEAs are bonded to the PV structure with electrically conducting material. The conducting electrode is applied at the scribed locations to achieve interconnection between the radiation side of the PV structure and the opposite side of the MEA electrode.

This instant invention also provides a PEC system that integrates the above-disclosed PEC cell with supporting structures and auxiliary components to become a stand-alone system for hydrogen generation. Such a system can be made completely self-sustained. The supporting structures and auxiliary components include the mounting mechanisms for various components, mechanism for water circulation through the PEC cell, and, when and where needed, containers to collect hydrogen and oxygen gases.

The instant invention further provides a method to fabricate the above-disclosed PEC cell and PEC system.

These above-disclosed PEC cell and system offer significant advantages such as high conversion efficiency, efficient electrolysis, low cost, and high durability. Hydrogen fuels generated using such a PEC system contain extremely low amount of carbon monoxide, making such hydrogen ideal for PEM fuel cell (PEMFC) where Pt is used as a catalyst. It is understood that Pt can be poisoned by CO gas and this would result in reduced performance. The above-mentioned PEC system, when used in combination with portable fuel cells, provides distributed, and portable, power generation. The energy can be stored in hydrogen form. Since there is radiation such as sunlight everyday, the required storage for such combined PEC/PEMFC system does not need to be large, thus resulting in reduced cost. The PEC system can be made lightweight and flexible, depending on the substrate selection and system material selection.

The integrated PV and MEA structure can also be used to generate hydrogen with radiations other than sunlight. Examples of such other radiations are: photons with other energy ranges, such as X-rays and Gamma rays, and electrons from beta emitting isotopes or other sources, alpha particle sources, or other energetic particle sources. In such uses, the optimum thickness of the radiation absorption layer may need to be different than the radiation absorption layers used for sunlight radiation.

The integrated PV and MEA structure are also useful as light-emitting devices. In such uses, hydrogen and oxygen (or air) are fed into the MEA, which generates a voltage. The gases are directed into the MEAs are made such that a forward electrical bias is applied by the MEA-generated voltage onto the semiconductor p-n junctions (PV structure as described above). The semiconductor junctions, under forward electrical bias, emit light. Such devices are useful as illuminators or displays.

The integrated PV and MEA structure are also useful as detectors or sensors. In such uses, hydrogen and oxygen (or air) are fed into the MEA, which generates a voltage. The gases are directed into the MEAs such that a reverse electrical bias is applied by the MEA-generated voltage onto the semiconductor p-n junctions (PV structure as described above). The semiconductor junctions, under reverse bias, generate an electrical pulse when a photon, electron, alpha, or other energetic particles enters the semiconductor junctions. Such devices are useful as detectors or sensors for a variety of particles.

The foregoing has outlined in broad terms the more important features of the invention disclosed herein so that the detailed description that follows may be more clearly understood, and so that the contribution of the instant invention to the art may be better appreciated. The instant invention is not to be limited in its appreciation to the details of the construction and to the arrangements of the components set forth in the following description or illustration in the drawings. Rather, the invention is capable of other embodiments and of being practiced and carried out in various other ways not specifically enumerated herein, Finally, it should be understood that the phraseology and terminology employed herein are for the purpose of description and should not be regarded as limiting, unless the specification specifically so limits the invention.

### BRIEF DESCRIPTION OF THE DRAWINGS

FIG. 1a is a schematic illustration of a cross-sectional view of a photoelectrochemical (PEC) cell which has a photovoltaic (PV) structure and a membrane electrode assembly (MEA) integrated and interconnected into one PEC cell.

FIG. 1b is a top view of the PEC cell depicted in FIG. 1a.

FIG. 1c is a perspective schematic illustration of a portion of the PEC cell shown in FIG. 1a.

FIG. 2 is a perspective schematic illustration of a portion of another embodiment of a PEC cell with radiation coming from the top.

FIGS. 3a and 3b are side elevational schematic illustrations of selected double-junction solar cells, as examples of suitable PV structures.

FIG. 4a and FIG. 4b are schematic side view and top view, respectively, of an end piece of the PEC cell for the collection of hydrogen and oxygen gases.

FIG. 5 is a schematic illustration of a PEC system.

### DETAILED DESCRIPTION OF THE PREFERRED EMBODIMENTS

In a first aspect, the present invention relates to a photoelectrochemical (PEC) cell that comprises:
at least one photovoltaic electrode that generates voltage under radiation;
at least one solid membrane electrode assembly that includes at least one solid polymer electrolyte and a first electrode on one side of the solid polymer and a second electrode on an opposing side of the solid polymer electrolyte;
at least one mechanism that collect gases from oxidation and reduction reactions, the mechanism including first and second compartments; and
at least one electrical connection between the photovoltaic electrode and the solid membrane electrode assembly.

In another aspect, the present invention relates to a PEC system comprising the photoelectrochemical (PEC) cell described above and, comprising at least one collecting mechanism to collect gases generated by the PEC cell.

In another aspect, the present invention relates to a method of making a PEC cell comprising:
a) forming a photovoltaic (PV) structure,
b) placing a reflective metal layer adjacent the PV structure,
c) forming a membrane electrode assembly,
d) forming electrically conducting end plates on each side of the membrane electrode assembly, and
e) forming at least one electrical connection between a radiation side of the PV structure and the membrane electrode assembly.
   Description of the PEC Cell

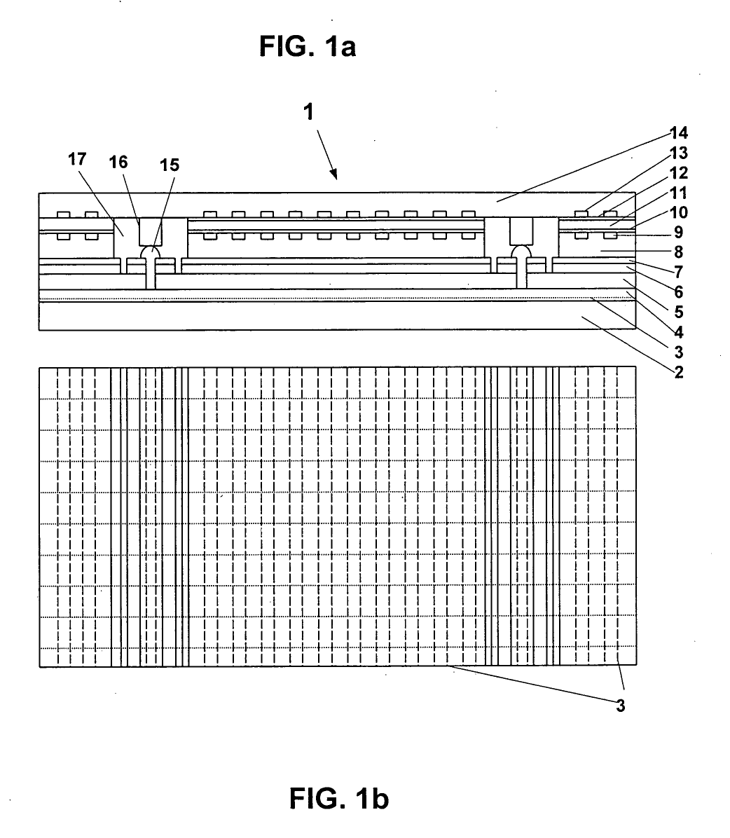

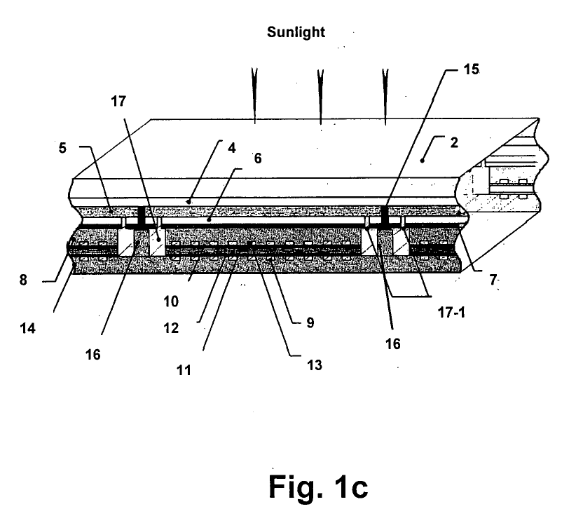

In one aspect, the present invention relates to two types of PEC cells based on solid polymer electrolytes. In one aspect, a solid-polymer based PEC cell has interconnect via holes to electrically connect the non-adjacent electrode of the PV structure and the electrode in the MEA. This method of creating interconnection, as depicted in FIG. 1, involves removing some films in the photovoltaic structure in selected areas, by scribing such as laser scribing or other methods, to achieve interconnection.

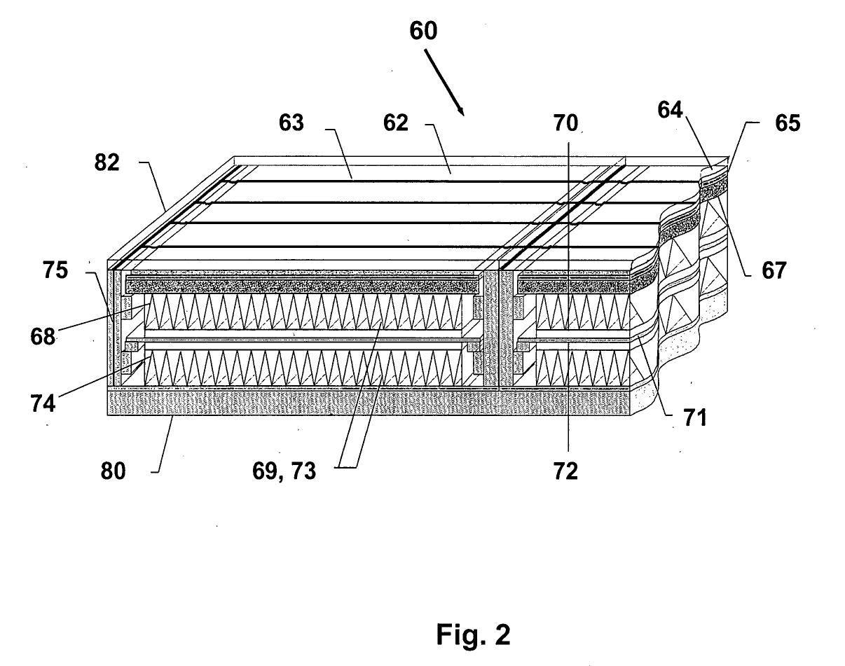

In another aspect, a solid polymer based PEC cell has interconnects embed in a container box. This other method of creating interconnection, as depicted in FIG. 2, does not require removing films from photovoltaic structure, but requires interconnection wires or mechanisms surrounding the photoelectrode, preferably inside the corrosion-resistant container, which confines the PEC cell and protects the electrical connections. It is to be understood that when similar structures/methods are described herein for one embodiment, other such similar structures/methods in other embodiments are considered to be also covered by the description herein and no repetition of such description of such structures/methods will be made.

Solid-Polymer Based PEC Cell with Interconnect Via Holes

An example of the photoelectrochemical (PEC) cell is depicted in FIG. 1. The PEC cell 1 comprises a photoelectrode, or as referred herein, a photovoltaic (PV) structure 4-7 and a membrane electrode assembly (MEA) 10-12. The PV structure is supported on a transparent substrate 2. In certain embodiments, the PV structure includes a grid 3, as is described in detail below.

In the PV structure, a semiconductor junction/stack 5 is sandwiched between a transparent conductor layer 4 on a radiation entering side and a transparent conductor layer 6 on an opposing side. It is to be understood that, in certain embodiments, the transparent conductor layers 4 and 6 can comprise a transparent conducting oxide material (i.e., referred to as TCO); for ease of discussion herein, such layers will generally be referred to as transparent conductor layers. A metal reflector 7 is adjacent the opposing side of the transparent conductor layer 6. A membrane electrode assembly (MEA) 10-12 comprises a solid polymer electrolyte 11 and two electrodes 10 and 12 on opposing sides of the solid polymer electrode 11. The MEA assembly 10-12 is sandwiched between two opposing end plates 8 and 14. The end plates 8 and 14, made of materials resistant to corrosion, define a plurality of compartments such as channels, grooves 9 and 13 or other corrosion-resistant porous materials such as a mesh. During use, as further described below, the hydrogen and oxygen that are generated collect in the openings such as channels or grooves 9 and 13 in the end plates. Water also flows through one or both of the channels 9 and 13 to flush out the gas bubbles and serve as the supply for the electrolysis reaction.

The electrical connection between the transparent conductor layer 4 and one of the end plates 14 is achieved by suitable means. In one embodiment, the electrical interconnection is achieved by suitable thin film removing method, such as by three thin film removing steps, using laser scribing, mechanical scribing, or other methods or a combination of these methods, that removes a desired sections of the transparent conductor layer 6 and the back-reflector layer 7 and also removes desired section of the semiconductor junction/stack 5 nearby. Conducting material 15 such as silver paste or evaporated metal is applied and a conducting piece 16 connects the conducting material 15 with the end plate 14. The empty space near the conducting material 15 and conducting piece 16 is filled with an insulating material or paste 17. It is to be understood that FIG. 1 only shows a section of the PEC structure and that a typical plate can have a plurality of MEA sections 10-12.

When radiation such as sunlight is irradiated on the semiconductor junction/stack 5 through the transparent substrate 2 and the transparent conducting layer 4, a voltage is generated. When a multiple-junction PV structure is used, the voltage can be around or higher than 1.6V, which is sufficient for water electrolysis. The sunlight radiation that is not absorbed by the semiconductor junction/stack 5 is reflected back to the semiconductor junction/stack 5 through the transparent conductor layer 6 by the back reflector layer 7. The voltage is then applied to the MEA 10-12 through the interconnecting materials 15 and 16 and by direct contact between the metal reflector layer 7 and the end plate 8. Hydrogen and oxygen are then generated in the channels 9 and 13 of the end plates 8 and 14. In embodiments where the semiconductor junction/stack 5 has an n-type semiconductor layer at the bottom side of FIG. 1a, i.e., closer to radiation entering side and a p-type semiconductor layer on the opposite side, the end plate 8 is positively biased and the end plate 14 is negatively biased. Reduction reaction then occurs at the electrode 12 and hydrogen comes out of channel 13. An oxidation reaction then occurs at the electrode 10 and oxygen comes out of channel 9. If the polarity of the semiconductor layers is reversed, the reduction and oxidation reactions will switch sides.

FIG. 1b is the top view of the PEC cell shown in FIG. 1a. Current collection grids 3 are shown in this figure. In certain embodiments, the application of the optional grids 3 is to assist current collection when the thin transparent conducting oxide material is not sufficiently conducting electrically.

Solid-Polymer Based PEC Cell with Interconnect Using Embedded Material

In another aspect, the present invention relates to a solid polymer-based PEC cell where the electrical interconnect is made through a grid 3 such as wires or foils bypassing the photovoltaic structure, such as being embedded in the container and protected by the corrosion-resistant container material, which could be plastic.

FIG. 2 is a perspective cross-sectional view of a section of another embodiment of a PEC/PV cell 60. In this figure, radiation enters the PEC cell from the top. The PEC cell 60 comprises a photovoltaic (PV) structure 65 and a membrane electrode assembly (MEA) 70-72. The photovoltaic structure 65, also referred to here as the photoelectrode, o comprises semiconductor layers, TCO layers on both sides of the semiconductor layers and a metal reflector layer. The PV structure is supported on a conducting substrate 67. One side 62, the top side, or radiation-entering side, of the conducting substrate 67, which could be stainless steel, is coated with a metal reflector while the other side of the conducting substrate is coated with corrosion resistant conductor. In certain embodiments, the PV structure includes a grid 63, as is described in detail below. The PV structure 65 is protected by a transparent encapsulation layer 64, which could be organic material such as EVA (ethyl-vinyl acetate) or an inorganic material such as silicon oxide.

It is to be understood that, in certain embodiments, the transparent conductor layers inside the PV structure can comprise an oxide material (i.e., referred to as TCO); for ease of discussion herein, such layers will generally be referred to as transparent conductor layers.

The conducting layer 67 for the PV structure also serves as an end plate for the membrane electrolyte assembly (MEA). The membrane electrode assembly 70-72 comprises a solid polymer electrolyte 71 and first and second electrodes 70 and 72 on opposing sides of the solid polymer electrode 71. Porous, conducting and corrosion-resistant materials 68 and 74, such as corrosion-resistant metal mesh, are placed on both sides of the MEA 70-72 to allow water to flow in and gasses to flow out through openings 69 and 73 in the porous materials 68 and 74, respectively. While the substrate for the PV structure confines MEA and porous materials on the top side (PV structure side), the opposite side of the MEA is confined by a bottom plate 80 of the PEC enclosure. Such a bottom plate is coated with corrosion-resistant conducting material, such as nickel, or other metals and alloys.

During use, as further described below, the hydrogen and oxygen that are generated collect in the openings (flow fields) 69 and 73. Water also flows through the flow fields 69 and 73 to flush out the hydrogen and oxygen gas bubbles. in other embodiments, instead of having porous material, the MEA could also be sandwiched by the end plates with channels and grooves, as described above in the section for solid-polymer based PEC with interconnect via holes. Vice versa, the MEA cell in this previous section could also be sandwiched by porous materials as described here.

When radiation such as sunlight is irradiated on the photoelectrode 65 through the transparent encapsulation layer 64, a voltage is generated. When a multiple-junction PV stack 65 is used, the voltage can be around or higher than 1.6V, which is sufficient for water electrolysis. The sunlight radiation that is not absorbed by the semiconductor junction/stack 65 is reflected back to the semiconductor junction/stack through the transparent conductor layer by the back reflector layer inside the PV stack 65. The voltage is then applied to the MEA 70-72 through an interconnecting material 75 and by direct contact between the PV structure 65 and top side of the MEA through porous conducting material 68. Hydrogen and oxygen are then generated in the flow fields 69 and 73 of the porous materials 68 and 74.

The triple-junction a-Si photoelectrode (i.e., the semiconductor junction/stack plus the TCO layers and back-reflector) 65 and polymer-electrolyte membrane electrode assembly (MEA) 70-72 electrolyze water through the interconnect 75. The interconnect 75 electrically connects an upper side of the photoelectrode/stack 65 to a bottom electrode 72 of the MEA 70-72. A lower side of the photoelectrode/stack 65 is in direct contact with the electrode 70 of the MEA 70-72.

In certain embodiments, the MEA structure 70-72 contains a solid polymer electrolyte 71 sandwiched between two opposing electrodes 70 and 72. The solid polymer electrolyte 71 could be a membrane, such as a Nafion® as further discussed herein. Water flows into the MEA 70-72 through a plurality of the flow fields 69 in the top and flow fields 73 in the bottom and to electrodes 70 and 72, respectively, continuing the water electrolysis and helping to drive out hydrogen and oxygen bubbles accumulated from the water electrolysis.

In the embodiment shown the PEC/PV 60 further includes a protective case 82 such as a plastic casing.

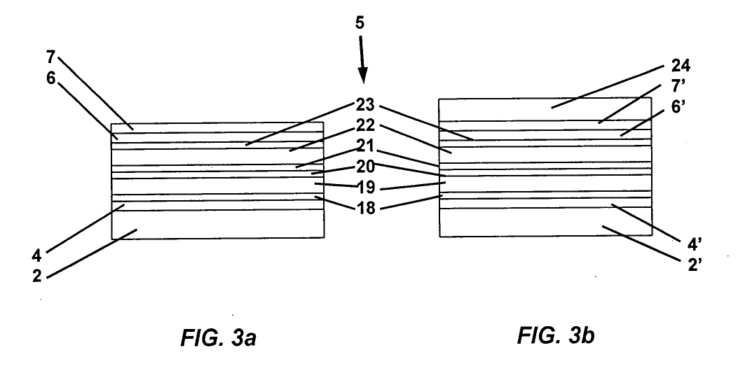

FIG. 3a and FIG. 3b show two examples of photovoltaic structures. In the embodiments shown, amorphous silicon (a-Si) and a-Si based alloys are used as the semiconductor junctions/stacks 5. The structure of semiconductor junction/stack 5, shown as layers 18-23 in FIG. 3 are either i) a-Si based n-type 18, intrinsic 19, p-type 20, n-type 21, intrinsic 22 and p-type 23 layers (nipnip layers), or ii) a-Si based p-type 18, intrinsic 19, n-type 20, p-type 21, intrinsic 22 and n-type 23 layers (pinpin layers). The nipnip layers create a positive voltage on the top under sunlight while the pinpin layers create a negative voltage on the top under sunlight. In FIG. 3a, the semiconductor stack 18-23 is deposited on a glass substrate 2 coated with a transparent conductor layer 4 adjacent to layer 18 and having a transparent conductor layer 6 adjacent to layer 23. A metal reflector layer 7 is adjacent to the transparent conductor layer 6. In FIG. 3b, the semiconductor stack 18-23 is deposited on a metal substrate 24 that has been coated with a metal reflective layer 7′ and a transparent conductor layer 6′. On the opposing side of the stack 18-23 there is a transparent conductor layer 4′ and then a transparent encapsulation layer 2′. The structure in FIG. 3b is an alternative to the structure shown in FIG. 3A and FIG. 1.

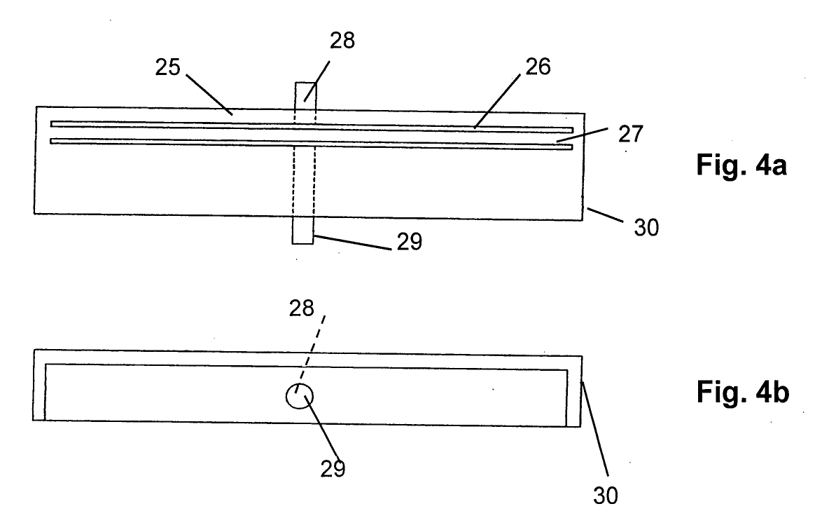

In FIGS. 4a and 4b, a first end adaptor 30 that collects hydrogen and oxygen gases is shown. The end piece 30 has a first opening 26 and a second opening 27, adapting to channels 13 and 9, respectively, which direct gases out of the PEC cell through gas tubes 28 and 29. FIGS. 4a and 4b are the front view and top view of end adaptor 30, respectively.

Description of the PEC System

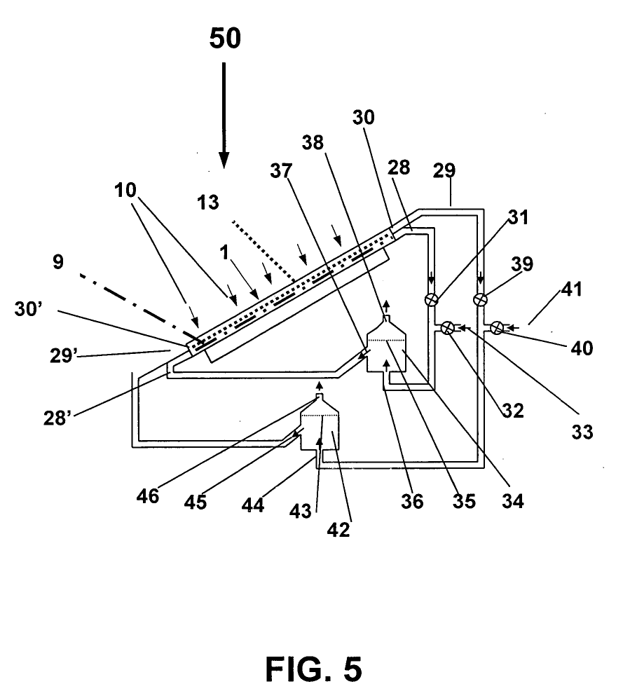

FIG. 5 shows a PEC system that uses the PEC cell 1 to generate hydrogen and oxygen. In one example, the n-layer of the semiconductor junction/stack 5 is closer to substrate 2 on the radiation side. Positive voltage is applied to electrode 10 and negative voltage is applied to electrode 12, shown in FIG. 1a. Hydrogen gas is generated in the first channel 13 and exits a first outlet tube 28 in the end piece 30. Oxygen is generated in the second channel 9 and exits a second outlet tube 29. To start the circulation during the initial operation, water can be circulated through channels 13 and 9 using a pump. However, after the water circulation is started the gravity will drive the gas bubbles to move upward. Depending on the dimension of the flow fields, this may cause self-sustained water circulation. Such water can also be used as the water supply for the chemical reaction. In the embodiment shown, first and second pumps 31 and 39 are for water circulation. The gases and water are circulated by the first and second pumps 31 and 39 through two gas collection containers 34 and 42, respectively, through first and second gas collection inlets 36 and 44, respectively. The hydrogen gas is collected at a first collection port 38 and the oxygen gas collected at a second collection port 46. Water flows out of the first and second gas collection containers 34 and 42 through at first and second recycling ports 37 and 45, respectively, back into the PEC channels 13 and 9 through inlet tubes 28′ and 29′ in the end piece 30′. When the water levels 35 and 43 in the first and second gas collection containers 34 and 42, respectively, are low, the respective water inlet value and switch 40 and 32 will open, allowing additional water to flow into the system via first and second water inlet ports 33 and 41, respectively.

Method to Make the PEC Cell and PEC System

There are several variations of methods to make the PEC system. An example is described here using the structure described in FIG. 1. A glass plate 2 is used as the substrate. Grids 3, such as silver or aluminum, are then applied using evaporation, screen printing or other methods. A transparent conductor layer 4, such as tin oxide or zinc oxide, is then deposited on the glass substrate 2, followed with the deposition of one or more semiconductor layers 5, such as a-Si based semiconductor layers. Another transparent conductor layer 6 and a metal reflector layer 7 are then deposited. Scribing steps are made using a suitable technique such as laser scribing to remove 1) metal back reflector layer 7 and transparent conductor 6 layer, and/or 2) the metal back reflector layer 7 and transparent conductor layer 6 and the semiconductor layers (stack) 5. A suitable conducting material 15 is applied to the center groove. Another piece of conductor material 16, with appropriate thickness, is installed over the conducting paste material 15. It is to be understood that in certain embodiments, the conducting paste 15 can be replaced with a metal layer made by, for example, evaporation.

In certain embodiments, the fabrication of the MEA 10-12, the electrode layers 10 and/or 12 can include a catalyst material. For example, nanoscale Pt particles are at least partially coated or applied onto a support such as a carbon powder. The Pt-coated powder is bonded (pressed) onto the electrodes 10 and 12. In such embodiments, the electrodes are made with carbon paper or carbon cloth.

In other embodiments, the Pt particles are bonded (pressed) onto both sides of the solid polymer electrolyte 11. In certain embodiments, a membrane comprises a polymer such as Nafion® (a product of Dupont is a perfluorinated polymer that contains small proportions of sulfonic or carboxylic ionic functional groups). The electrodes 10 and 12 are then applied onto both sides of the solid electrolyte 11.

In certain embodiments, the end plates 8 and 14 comprise corrosion-resistant conductor such as sheets of stainless steel or thin layers of graphite, or other conducting material, which already have grooves or channels 9 and 13 pre-fabricated in the end plates 8 and 14. The endplates 8 and 14 are cut, together with MEA 10-12, into appropriate sizes. The sizes are such that they fit between the sections separated by laser scribing. The “end plate 8/MEA 10-12/end plate 14” stack is then installed onto the PV structure 2-7. In certain embodiments, the “end plate 8/MEA 10-12/end plate 14” stack can be pressed onto the PV structure under suitable conditions.

In certain embodiments, where the conduction is not deemed to be sufficient, a conducting paste or liquid meal alloy 17 can be used to enhance conductivity of the interconnect materials 15 and 16. The insulating paste 17 is applied in the cavity 17-1 around interconnect piece 16 to electrically isolate the MEA 10-12 from touching the interconnect piece 16. The other end plate 14, having pre-fabricated grooves therein, is then installed as the other end plate. This end plate 14 also mechanically protects the PEC cell. In certain embodiments, another insulating coating (not shown) is applied on top to electrically isolate the PEC cell from the environment.

The first and second end adapter pieces 30 and 30′, described in FIG. 4, can be machined in a suitable manner. The two end pieces 30 and 30′, with gas tubes 28, 29, 28′ and 29′, are installed to the PEC cell for water inlet and water/gas outlet. Circulation pumps, water inlet values, and the gas collection containers are installed using gas tubes. Hydrogen and oxygen can be collected at the port 38 and the port 46, respectively, or vice versa, depending on the polarity of the photovoltaic structure.

Method to Make Hydrogen and Oxygen

The PEC system 50, with an example shown in FIG. 5, is used to generate hydrogen and oxygen. The system is installed under radiation of sunlight or other suitable radiation such that the radiation enters through the top cover substrate 2. Water is added in ports 41 and 33; hydrogen and oxygen gases are collected at ports 38 and 46, respectively. In using the PEC system, the PEC cell is preferably tilted so that the top cover 2 faces the radiation such as the sunlight.

Description of a Light Emitting Structure and a Detector

The integrated structure, depicted in FIG. 1, can also be used as a light-emitting device. Hydrogen and oxygen (or air) are directed into the system from channels 9 and 13. Through a fuel cell process, a voltage is generated. The selection of channels for hydrogen and oxygen is such that the voltage generated by the MEA applies a forward bias on the semiconductor pn or pin junctions. Light then emits from these junctions due to the high level of radioactive recombinations of electrons and holes recombining at the semiconductor junctions. The light can be emitted through glass 2. Photons moving upward toward the transparent conductor layer 6 and metal back reflector layer 7 will be reflected back toward glass 2. Such a device is useful as an illuminator or a display.

By reversing the flow of the gases into the channels, a negative bias could be applied to the semiconductor junctions. In this case, the integrated structure can be used as a detector for photons, electronics, or other particles.

For example, in certain embodiments, the p-layer in the semiconductor stack 5 is closed to the TCO later 4 and the n-layer in the semiconductor stack 5 is closer to the TCO layer 6. If hydrogen flows into channels 9 and oxygen flows into channel 13, the semiconductor stack 5 is then under forward bias and the device is a light emitting diode. If oxygen flows into channel 9 and hydrogen flows into channels 13, the semiconductor stack is then under reverse bias and can be used as a detector.

Method to Make the Light Emitting Structure and a Detector

The method to make light emitting structures and detectors and other such devices is similar to the description of method for the integrated PEC cell above.

Other Applications

The integrated PV and MEA structure can also be used to generate specially needed gases in a place that it is hard to reach. For example, using tritium as a source of electron radiation, the PV structure generates a voltage, which drives the electrochemical reaction at the MEA, creating gases needed for special purposes. Since some radio-active isotopes have long life times, such a device provides special gases, depending on the chemical reactions selected, for a long time.

### EXAMPLE 1

An example of the semiconductor junction/stack 5 in the PV structure 4-7 is a two-junction a-Si/a-SiGe solar cell. The total voltage can be made to be around to 1.6V or higher at operating point, when relative low Ge content is used for the absorber layers. In one specific embodiment, the structure comprises: glass/grids/SnO/a-SiC p/a-Si intrinsic/a-Si n/s-SiC p/a-SiGe intrinsic/a-Si n/ZnO/aluminum.

The thickness of the respective layers are approximately: 1 mm/10 μm/1 μm/10 nm/150 nm/10 nm/10 nm/150 nm/200 nm/150 nm, respectively, for optimum sunlight radiation.

In certain specific embodiments, the length of each sections of end plate 8 is around 5 to 10 cm while the width of the laser scribing is about 0.1 mm.

In certain specific embodiments, the thickness and bandgap of a-Si and a-SiGe intrinsic layers may be adjusted such that the two component solar cells generate about the same electrical current under the radiation specified. For electron radiation, for example, it is desired that the thickness of the i-layers be much thicker than for photon radiation.

Various triple-junction solar cells, including, for example: a-Si/a-SiGe/a-SiGe, a-Si/a-Si/a-SiGe, a-Si/a-SiGe/μc-Si, a-Si/μc-Si/μc-Si solar cells, are useful to generate sufficient voltage instead of using a tandem solar cells with two junctions.

In certain embodiments, the photovoltaic electrode comprises at least one of the following solar cell types: amorphous silicon (a-Si), cadmium telluride (CdTe), copper indium diselenide (CuInSe₂), copper indium gallium diselenide (CIGS), III-V (GaAs, InP etc), crystalline silicon (c-Si), thin film silicon (thin-Si), or variations and combinations thereof. Further, in certain embodiments, the photovoltaic electrode has multiple junctions including two-junctions, three junctions and more junctions wherein sufficient voltage is generated for electrolysis. In still other embodiments, at least one of the photovoltaic junctions in the multiple-junction photoelectrode uses amorphous silicon.

In other embodiments, triple-junction a-Si/a-SiGe/a-SiGe, a-Si/a-Si/a-SiGe, a-Si/A-SiGe/μc-Si, or a-Si/μc-Si/μc-Si solar cells are also used to generate sufficient voltage instead of using tandem solar cells with two junctions.

### EXAMPLE 2

There are different ways water can be directed into the MEA. In addition to the methods described above, another way to direct water into the electrolyte is to create channels in the solid polymer electrolyte. In such embodiment, water can flow directly into the electrolyte instead of going through the channels on the end plate. Also, in other embodiments, water can flow only through the end plate that is closest to the electrode where water is consumed.

The above detailed description of the present invention is given for explanatory purposes. It should be understood that all references cited herein are expressly incorporated herein by reference. It will be apparent to those skilled in the art that numerous changes and modifications can be made without departing from the scope of the invention. Accordingly, the whole of the foregoing description is to be construed in an illustrative and not a limitative sense, the scope of the invention being defined solely by the appended claims.

1. A photoelectrochemical (PEC) cell, comprising:
at least one photovoltaic electrode that generates voltage under radiation;
at least one solid membrane electrode assembly (MEA) that includes at least one solid polymer electrolyte and a first electrode on one side of the solid polymer and a second electrode on an opposing side of the solid polymer electrolyte;
at least one mechanism that collect gases from oxidation and reduction reactions; and
at least one electrical connection between the photovoltaic electrode and the solid membrane electrode assembly.

2. The PEC cell as in claim 1, wherein the photovoltaic electrode generates sufficient voltage under radiation for electrolysis.

3. The PEC cell as in claim 2, wherein the photovoltaic electrode comprises at least one of following semiconductor junctions: amorphous silicon (a-Si), cadmium telluride (CdTe), copper indium diselenide (CuInSe₂), copper indium gallium diselenide (CIGS), III-V (GaAs, InP etc), crystalline silicon (c-Si), thin film silicon (thin-Si), or variations and combinations thereof.

4. The PEC cell as in claim 3, wherein at least one of the photovoltaic junction comprises amorphous silicon.

5. The PEC cell as in claim 3, wherein the semiconductor junction comprises multiple junctions.

6. The PEC cell as in claim 5, wherein the semiconductor junction comprises at least one metal oxide.

7. The PEC cell as in claim 6, wherein the metal oxide comprises TiO₂, WO₃ or Fe₂O₃ and combinations thereof.

8. The PEC cell as in claim 6, wherein the metal oxide is alloyed with at least one another material selected from Ca and/or Mg, to increase radiation absorption.

9. The PEC cell as in claim 5, wherein the semiconductor junction comprises at least one III-V compound semiconductor.

10. The PEC cell as in claim 9, wherein the III-V compound semiconductor includes at least one of: InGaN, GaPN, GaAsPN, GaP and combinations thereof.

11. The PEC cell as in claim 5, wherein the semiconductor junction comprises at least one Group IV semiconductor or semiconductor alloy.

12. The PEC cell as in claim 11, wherein the Group IV semiconductor or semiconductor alloy includes at least one of: Si, C, Ge, Sn, SiC, GeC and combinations thereof, in both amorphous and crystalline form.

13. The PEC cell as in claim 1, wherein the radiation comprises photons, electrons or other energy-carrying radiations and particles.

14. The PEC cell as in claim 13, wherein the radiation comprises solar radiation.

15. The PEC cell as in claim 1, wherein the solid membrane electrode assembly comprises at least one ion-exchange membrane.

16. The PEC cell as in claim 15, wherein the membrane comprises at least one of a cation exchange membrane or an anion-exchange membrane.

17. The PEC cell as in claims 15, wherein the ion-exchange membrane is installed behind the photovoltaic electrode and away from the radiation to allow for maximum radiation to reach the photovoltaic electrode.

18. The PEC cell as in claim 17, wherein the membrane comprises a perfluorinated polymer that contains small proportions of sulfonic or carboxylic ionic functional groups.

19. The PEC cell as in claim 1, wherein the mechanism for collecting gases comprises first and second electrically conducting end plates, the first electrically conducting end plate defining a first compartment, and the second electrically conducting end plate defining a second compartment.

20. The PEC as in claim 19, wherein the end plates comprise a corrosion-resistant conductor or a conductor coated with a thin corrosion-resistant conducting layer.

21. The PEC cell as in claim 19 wherein the first and second compartments comprise a plurality of channels in each of the opposing electrically conducting end plates.

22. A PEC system comprising:
i) a photoelectrochemical (PEC) cell, comprising:
a substrate that is substantially transparent to radiation;
at least one photovoltaic electrode that generates voltage under radiation;
at least one solid membrane electrode assembly that includes at least one solid polymer electrolyte and a first electrode on one side of the solid polymer and a second electrode on an opposing side of the solid polymer electrolyte;
at least one mechanism that collect gases from oxidation and reduction reactions; and
at least one electrical connection between the photovoltaic electrode and the solid membrane electrode assembly; and,
ii) at least one collecting mechanism to collect gases generated by the PEC cell.

23. The PEC system as in claim 22 comprising at least one end adaptor that delivers water to the PEC cell.

24. The PEC system as in claim 22 comprising collecting water mixed with oxygen or hydrogen bubbles from the PEC cell.

25. The PEC system as in claim 22, wherein the collecting mechanism comprises
a first collection container for receiving a first gas generated in the first compartment;
a second collection container for receiving a second gas generated in the second compartment; and
a supply of water for circulating through the first and second compartments.

26. The PEC system as in claim 25, wherein hydrogen gas is generated in the a compartment in the PEC cell and exits from a first outlet tube operatively connected to the first collection container, and wherein oxygen is generated in a second compartment in the PEC cell and exits from a second outlet tube operatively connected to the second collection container.

27. The PEC system as in claim 26, further comprising first and second pumps for circulating water wherein gases and water are circulated by the pumps through the first and second gas collection containers, respectively, so that hydrogen is collected at a first collection port in the first gas collection container and oxygen is collected at a second collection port in the second gas collection container; and wherein water flows from first and second recycling ports in the first and second collection containers, respectively, back into the first and second top compartments respectively, through third and fourth inlet tubes operatively connected to a second end adaptor on and opposing end of the PEC cell.

28. The PEC system as in claim 27, further comprising first and second water inlet valves and switches operatively connected via first and second ports, respectively, to the first and second gas collection containers to allow additional water to flow into the system.

29. A method of making a PEC cell comprising:
a) forming a photovoltaic (PV) structure,
b) placing a reflective metal layer adjacent the PV structure,
c) forming a membrane electrode assembly,
d) forming electrically conducting end plates on each side of the membrane electrode assembly, and
e) forming at least one electrical connection between a radiation side of the PV structure and the membrane electrode assembly.

30. The method as in claim 29 wherein the photovoltaic (PV) structure is formed by
i) depositing a first transparent conductor layer on a substrate,
ii) depositing at least one semiconductor junction comprising a photovoltaic electrode on the first transparent conductor layer, and
iii) depositing a second transparent conductor layer on an opposing side of the semiconductor junction.

31. The method as in claim 29 wherein the membrane electrode assembly is formed by:
i) forming a solid polymer electrolyte, and
ii) forming opposing electrodes on each side of the solid polymer electrolyte.

32. The method of making the PEC cell described in claim 30, wherein the substrate comprises a metal foil or plate.

33. The method of making the PEC cell described in claim 29, wherein the reflective metal layer comprises an aluminum layer.

34. The method of making the PEC cell described in claim 30, wherein the first transparent conductor layer comprises at least one of tin oxide, zinc oxide indium oxide, indium tin oxide, or combinations and mixtures thereof.

35. The method of making the PEC cell described in claim 30, wherein the PV structure is isolated using a scribing process that includes laser scribing.

36. The method of making the PEC cell described in claim 30, wherein the semiconductor junction comprises a-Si based semiconductor layers.

37. The method of making the PEC cell described in claim 30, wherein a thin layer of catalyst is deposited on the second transparent conductor layer.

38. The method of making the PEC cell described in claim 30, further includes depositing a catalyst comprising a thin layer of carbon powder with micrometer sized spheres that support nanometer sized Pt particles on the substrate.

39. The method of making the PEC cell described in claim 38, wherein the carbon powder is pressed or bonded to the transparent conductor layer.

40. The method of making the PEC cell described in claim 39, wherein the catalyst is applied to selected regions so that the catalyst does not substantially block incoming radiation.

41. The PEC system as in claim 40, wherein hydrogen gas is generated in a first compartment and exits from a first outlet tube operatively connected to the first collection container, and wherein oxygen is generated in a second compartment and exits from a second outlet tube operatively connected to the second collection container.

42. The PEC system as in claim 41, further comprising first and second pumps for circulating water wherein gases and water are circulated by the pumps through first and second gas collection containers, respectively, so that hydrogen is collected at a first collection port in the first gas collection container and oxygen is collected at a second collection port in the second gas collection container; and wherein water flows from first and second recycling ports in the first and second collection containers, respectively, back into the first and second top compartments respectively, through third and fourth inlet tubes operatively connected to a second end adaptor on and opposing end of the PEC cell.

43. The PEC system as in claim 42, further comprising first and second water inlet valves and switches operatively connected via first and second ports, respectively, to the first and second gas collection containers to allow additional water to flow into the system.

44. The PEC cell of claim 1, wherein the photovoltaic electrode comprises: metal substrate, metal reflector, first transparent conducting oxide (TCO), n-type a-Si layer, intrinsic a-SiGe layer or microcrystalline silicon layer, p-type a-Si based layer, n-type a-Si layer, intrinsic a-Si layer or a-SiGe layer, p-type a-Si based layer, n-type a-Si layer, intrinsic a-Si layer, p-type a-Si based layer (nipnipnip layers), second TCO layer.

45. The PEC cell of claim 1, wherein the photovoltaic electrode comprises: metal substrate, metal reflector, first transparent conducting oxide (TCO) layer, p-type a-Si based layer, intrinsic a-SiGe layer or microcrystalline silicon layer, n-type a-Si layer, p-type a-Si based layer, intrinsic a-Si or a-SiGe layer, n-type a-Si layer, p-type a-Si based layer, intrinsic a-Si layer, n-type a-Si layer (pinpinpin layers), second TCO layer.

46. A light illuminating device comprising the PEC cell of claim 1.

47. A particle or radiation detector device comprising the PEC cell of claim 1.

48. A device for generating gases comprising the PEC cell of claim 1.

49. The device of claim 48 for generating hydrogen and oxygen.
